(19) United States
(12) Patent Application Publication
(10) Pub. No.: US 2005/0231188 A1
(43) Pub. Date: Oct. 20, 2005

(54) Method and circuit for conducting AC offset current compensation and testing device using the same

(75) Inventors: Yauo-Nan Wang, Taipei City (TW); Chien-Chao Chu, Sijhih City (TW); Kuang-Tsen Huang, Sinjhuang City (TW)

Correspondence Address: BUCKNAM AND ARCHER, 1077 NORTHERN BOULEVARD, ROSLYN, NY, 11576, US

(73) Assignee: CHROMA ATE INC.

(21) Appl. No.: 10/981,095

(22) Filed: Nov. 4, 2004

(30) Foreign Application Priority Data
Apr. 16, 2004 (TW) 093110649

(51) Int. Cl. G01R 33/00

(52) U.S. Cl. 324/117 R

(57) ABSTRACT

The invention disclosed a method and circuit for conducting an AC offset current compensation and a testing device using the same, capable of providing a high voltage measurement that fulfils a voltage resistance condition of safety regulation, so that it is possible to achieve the requirement of increasing the test accuracy on voltage resistance by controlling the magnitude, phase and offset current compensation of the voltage output.

### FIELD OF THE INVENTION

The present invention relates to a method for measuring the safety specification of a tested object, especially to a method and circuit for conducting an AC offset current compensation and a testing device using the same, capable of providing a precise measurement for the safety specification test conducted on the tested object.

### BACKGROUND OF THE INVENTION

In addition to ordinary electrical appliance such as heater and hair dryer, there are more and more electronic parts are subjected to the test of safety specification of the voltage resistance by means of a test machine.

When conducting the test on products, there is no rigid requirement on the offset current of the test equipment itself because most of the products are composed of many kinds of material and have higher total current. However, when conducting the test on materials, due to the small current of a single source, the offset current of the test equipment itself can affect the accuracy of measurement. Other than that, there are increasing newer and higher requirement of voltage test applied to further degrade the accuracy of measurement.

The existing method for generating high AC voltage is using a transformer to increase the output voltage, a higher voltage needs more turns for the coils of transformer, which in terms increases the capacitance between the coils and the housing and results in the increase of the capacitive offset current. A conventional high voltage measurement system deals with the offset current generated by itself by pre-storing an offset current before connecting to the tested object in a built-in microprocessor and subtracting such value from the measured value to increase the accuracy. In principle, the above calculation can remove the influence applied on the actual test by the offset current of the test equipment, however, it is not practical to simply subtract a pre-stored value in an AC voltage measurement systems having both real and imaginary components in its measured value. Therefore, the following equation is used to achieve an accurate measurement when conducting the test on a resistive load: Measured Current=√[(Resistive Current)²+(Capacitive Current)²]where the resistive current and the capacitive current refer to the real component and the imaginary component of the measured value, respectively.

However, it is impossible to achieve an accurate measurement through such calculation if the tested object has a capacitive characteristic.

Therefore, in order to achieve an error free measurement, one must reduce the capacitive offset current caused by the transformer to a level as low as possible. However, it is impossible to eliminate such phenomenon in the practical measurement, because the higher capacitive offset current resulted from more turns in the transformer coils needed for a higher voltage output.

Based on the inefficiency of a conventional test machine using the above mentioned method and circuit, the inventor developed after intensive thinking and study a novel method and circuit of conducting an AC offset current compensation and a testing device using the same, capable of providing a high voltage measurement that fulfils a voltage resistance condition of safety regulation.

The major object of present invention is to simplify the high AC voltage measurement procedure conducted on the electrical appliance without performing an error compensation of the equipment itself.

The major object of present invention is to simplify the high AC voltage measurement procedure conducted on the electrical appliance without performing an error compensation of the equipment itself.

The further object of present invention is to improve the resistive and capacitive test error shown in the existing measurement equipment due to various materials.

### SUMMARY OF THE INVENTION

An object of present invention is to provide a method and circuit of conducting an AC offset current compensation and a testing device using the same to be used in the application of safety specification test equipment.

The present invention has made use of the characteristics such as a linear proportion between the offset current and working voltage due to a constant capacitance existing in the offset loop as well as a current generated by applying voltage across a capacitor with 90 degree phase leading compared to the applied voltage, to provide an test signal of no offset capacitive effect by generating a signal of 90 degree phase shift through a phase shift circuit from the voltage output of the primary coil (low voltage side) and then comparing an offset current signal of the secondary coil (high voltage side) with said phase-shifted low voltage through a differential amplifier.

A test device using such method and circuit comprises at least a voltage resistance test unit, which is equipped with an offset current compensation circuit so that the offset current generated by internal capacitive effect is compensated before a test signal is output from the secondary coil of the test device, therefore it is possible to eliminate the test error caused by the offset current via said processed test signal.

### BRIEF DESCRIPTION OF DRAWINGS

FIG. 1 is a schematic block diagram of an AC offset current compensation circuit in accordance with present invention.

FIG. 2A shows the waveform measured in a tested device without the AC offset current compensation circuit of present invention.

FIG. 2B shows the waveform measured in a tested device with the AC offset current compensation circuit of present invention.

### DETAILED DESCRIPTION OF THE INVENTION

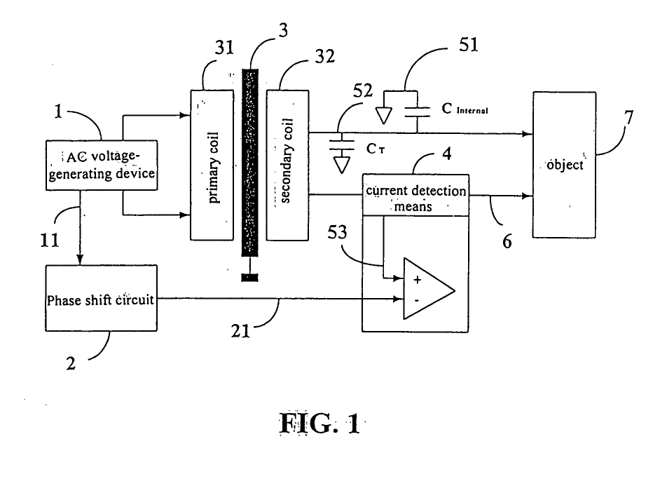

Referred to FIG. 1, an AC offset current compensation circuit in accordance with present invention comprises: an AC voltage-generating device 1 functioning as an independent controller for a voltage/frequency output device coupled to a transformer and a phase shift circuit; a phase shift circuit 2 capable of outputting a phase signal to a current detection device; a transformer 3 receiving a low voltage input at the primary coil end 31 while outputs a high voltage at the secondary coil end 32 to provide test voltage for a tested object; and a current detection device 4 conducting current measurement with functions of offset current compensation and comparison.

In the high voltage test device, there are two sources of offset capacitance, a high voltage wiring offset capacitor CINTERNAL 51 existing in the circuit, while a high voltage transformer offset capacitor CT 52 existing between the coil and the ion core of the transformer.

Thus, the present invention has made use of the characteristics such as a linear proportion between the offset current and working voltage due to a constant capacitance existing in the offset loop as well as a current is generated by applying voltage across a capacitor with 90 degree phase leading compared to the applied voltage, to conduct the process of self compensation.

Accordingly, while conducting the test, a signal inputted to the AC voltage-generating device 1 is passed through a transformer 3 with its voltage raised and outputted via a high voltage output 32, a voltage 11 of the low-voltage side is used to generate a voltage signal 21 with 90 degree phase shift through a phase shift circuit 2, so as to have the gain controlled to the same value as the offset current to be compensated. A current detection device 4 is then used to subtract said voltage signal from the offset current signal 53 generated by said offset capacitance (CINTERNAL+CT) at the high voltage side, and result in a better, almost offset capacitive effect free high voltage current 6 that can be used as the test signal for testing an object 7.

The method and circuit of conducting an AC offset current compensation as stated is usually used in a electric safety specification analysis device, such as a voltage resist type Safety Tester available from CHROMATM ATE, INC, in the following context a verification for one of such device will be provided.

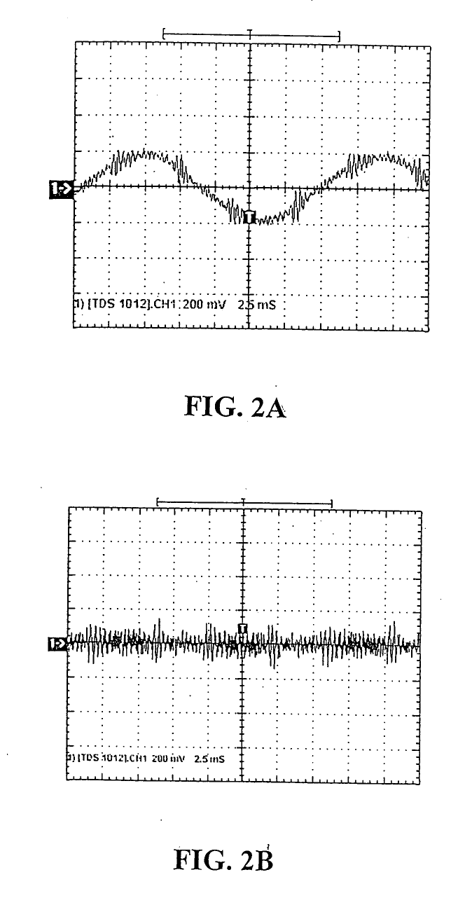

First, record the current display of said device before the offset current self-compensation circuit of present invention is inserted. The settings before the test are: WAC 5.0 kV, Hi_Lim 2.0 mA, Test_Time OFF After pressed the start key to have a continuous 5 k Vac voltage output from said test device, an offset current display value of 0.168 mA was observed. As shown in FIG. 2A, the waveform of such output is recorded by means of an oscilloscope.

Next, the offset current self-compensation circuit of present invention was used in the same test device. The settings before the test are the same as above.

After pressed the start key to have a continuous 5 k Vac voltage output from said test device, an offset current display value of 0.03 mA, which is much smaller than the one without the offset current self-compensation circuit, was observed. As shown in FIG. 2B, the waveform of such output is recorded by means of an oscilloscope.

Thus, by comparing the waveforms and the offset currents, one can conclude that the offset current self-compensation circuit of present invention has compensated or reduced the offset current generated by the high voltage device and greatly reduce the test error resulted from such offset current.

In addition, the present invention has made the following improvement:
1. A new AC high-voltage test process for electric products, which no longer need to conduct the error compensation of the device itself, is proposed.
2. The cost spent on dealing with the offset current result from a high-voltage generating device is greatly reduced.
3. An improvement is made on the resistive and capacitive test error shown in the existing measurement equipment due to various materials.

To summary, the present invention has provided a novel invention exhibiting both industrial applicability and advancing. Above described is a preferred embodiment of the invention but not intended to be the limit of the invention, various change and modification without departing from the claim and its equivalence must be considered as fall within the scope of the invention.

| Numerals | Descriptions |
|---|---|
| 1 | AC voltage-generating device |
| 2 | phase shit circuit |
| 3 | transformer |
| 4 | current detection means |
| 6 | high voltage current |
| 7 | tested object |
| 11 | voltage of low-voltage end |
| 21 | voltage signal |
| 31 | primary coil |
| 32 | secondary coil (high voltage output) |
| 51 | offset capacitance CINTERNAL |
| 52 | offset capacitance CT |
| 53 | signal of offset current |

1-3. (canceled)

4. An AC offset current compensation circuit comprises:
an AC voltage-generating device functioning as an independent controller for a voltage/frequency output device coupled to a transformer and a phase shift circuit;
the phase shift circuit capable of outputting a phase signal to a current detection device;
the transformer for receiving a low voltage input at the primary coil end while outputting a high voltage at the secondary coil end to provide test voltage for a tested object; and
the current detection device for conducting current measurement with functions of offset current compensation and comparison;
wherein said AC voltage-generating device produces an output to said phase shift circuit which generates a phase-shifted signal, after the leakage current signal on the high voltage end of the transformer is compared with the phase-shifted signal, a test signal with an appropriate offset curent compensation is thus created to provide a signal without capacitance leakage to the tested object.

5. The AC offset current compensation circuit as set forth in claim 4, wherein a voltage signal with phase shift generated via the phase shift circuit is used to have the gain controlled to the same value as the offset current to be compensated.

6-7. (canceled)
